(19) United States
(12) Patent Application Publication
(10) Pub. No.: US 2025/0113678 A1
(43) Pub. Date: Apr. 3, 2025

(54) OPTOELECTRONIC COMPONENT, AND METHOD FOR MANUFACTURING AN OPTOELECTRONIC COMPONENT

(71) Applicant: ams-OSRAM International GmbH, Regensburg (DE)

(72) Inventors: Ulrich STREPPEL, Regensburg (DE); Stefan GRÖTSCH, Bad Abbach (DE); Hansjörg SCHÖLL, Bad Abbach (DE)

(21) Appl. No.: 18/833,290

(22) PCT Filed: Jan. 26, 2023
(86) PCT No.: PCT/EP2023/051902

§ 371 Date: Jul. 25, 2024

(30) Foreign Application Priority Data
Jan. 28, 2022 (DE) 10-2022-102-014.2

(51) Int. Cl. H10H 20/856; H10H 20/01; H10H 20/80; H10H 29/14

(52) U.S. Cl. CPC H10H 20/856; H10H 20/0363; H10H 20/882; H10H 29/142

(57) ABSTRACT

The invention relates to an optoelectronic component comprising an optoelectronic semiconductor chip having an emission surface which is located on an upper side and is designed to emit light into an emission space. The emission surface is laterally delimited by a cover which has: a first portion that annularly delimits the emission surface; and a second portion. The cover is designed in such a way that light incident on the second portion of the cover from outside the optoelectronic component is predominantly reflected. Light emitted from the emission surface towards the cover is predominantly deflected by the cover in such a way that it is not specularly reflected into the emission space.

The present invention relates to an optoelectronic component and a method for manufacturing an optoelectronic component.

Optoelectronic components exist in diverse variants and designs. Optoelectronic components are known in which a reflective potting is arranged around an emission surface. Optoelectronic components equipped with a projection optics unit are likewise known.

One object of the present invention is to provide an optoelectronic component. A further object of the present invention is to specify a method for manufacturing an optoelectronic component. These objects are achieved by an optoelectronic component and by a method for manufacturing an optoelectronic component comprising the features of the independent claims. Various developments are specified in the dependent claims.

An optoelectronic component comprises an optoelectronic semiconductor chip comprising an emission surface arranged on a top side, the emission surface being provided to emit light into an emission space. The emission surface is laterally bounded by a cover comprising a first section, which ring-shapedly bounds the emission surface, and a second section. The cover is configured such that light incident on the second section of the cover from outside the optoelectronic component is predominantly reflected. Light emitted by the emission surface in the direction of the cover is predominantly deflected by the cover such that it is not specularly reflected into the emission space.

The fact that light incident on the second section of the cover from outside the optoelectronic component is predominantly reflected in the case of this optoelectronic component advantageously reduces the risk of light incident from outside causing a material degradation, for example as a result of a thermal effect. In this case, the light incident from outside may be sunlight, for example. The fact that the cover is configured such that light emitted by the emission surface in the direction of the cover is predominantly deflected by the cover such that it is not specularly reflected into the emission space advantageously reduces the risk of unwanted scattered light passing into the emission space. These two functionalities of the cover are realized in the case of this optoelectronic component by virtue of the cover comprising two sections.

In one embodiment of the optoelectronic component, the latter comprises a projection optics unit arranged over the emission surface such that light emitted into the emission space passes into the projection optics unit. The projection optics unit may be provided for example for projecting the light emitted by the emission surface into a target space. Advantageously, in the case of this optoelectronic component, light emitted by the emission surface in the direction of the cover is not projected, or is projected only to a small extent, into the projection optics unit and is therefore not undesirably projected into the target space either.

In one embodiment of the optoelectronic component, the emission surface covers a part of the top side of the optoelectronic semiconductor chip. In this case, the first section of the cover is arranged at least sectionally on the top side of the optoelectronic semiconductor chip. In this way, the cover may advantageously closely enclose the emission surface of the optoelectronic semiconductor chip.

In one embodiment of the optoelectronic component, light emitted by the emission surface in the direction of the cover is guided past the optoelectronic semiconductor chip at least partly in an opposite direction to the emission space. Advantageously, this particularly effectively prevents said light from undesirably passing into the emission space and into a projection optics unit possibly arranged there.

In one embodiment of the optoelectronic component, the second section is radially outwardly adjacent to the first section. What is advantageously achieved as a result is that that part of the cover which faces the emission surface is formed by the first section, while the second section of the cover forms a part of the cover which faces the emission space.

In one embodiment of the optoelectronic component, the second section comprises a contact area adjoining the first section. In this case, light emitted by the emission surface in the direction of the cover is at least partly reflected at the contact area. The contact area may advantageously be configured and oriented such that light reflected at the contact area is predominantly not specularly reflected into the emission space.

In one embodiment of the optoelectronic component, the contact area comprises a concave shape. This may be achieved in a simple manner by virtue of the fact that a part of the first section of the cover which faces the second section comprises a convex shape. The concave shape of the contact area may advantageously cause the light emitted by the emission surface in the direction of the cover to be collected, and thereby prevent specular reflection into the emission space.

In one embodiment of the optoelectronic component, the contact area is oriented toward the top side of the optoelectronic semiconductor chip. This advantageously prevents light that is emitted by the emission surface in the direction of the cover and is reflected at the contact area from being specularly reflected into the emission space.

In one embodiment of the optoelectronic component, the first section and the second section comprise different optical properties, in particular a different transparency and/or a different reflectivity. This advantageously makes it possible for the cover of the optoelectronic component to fulfil a plurality of different functionalities simultaneously.

In one embodiment of the optoelectronic component, the first section and the second section comprise different materials. Advantageously, it is possible particularly easily as a result to configure the first section and the second section with different optical properties.

In one embodiment of the optoelectronic component, the second section comprises a higher proportion of light-scattering particles than the first section. What may advantageously be achieved as a result is that the second section comprises a higher reflectivity than the first section of the cover.

In one embodiment of the optoelectronic component, the first section comprises a material which comprises a transmission of at least 30% given a reference thickness of 100 μm. In this case, the first section advantageously comprises a sufficient transmission to achieve the effect that the light emitted by the emission surface in the direction of the cover is predominantly reflected at the first section of the cover.

In one embodiment of the optoelectronic component, a surface of the first section that is not covered by the second section comprises a microstructuring. The microstructuring may be a roughening, for example. Advantageously, this microstructuring achieves the effect that light emitted by the emission surface in the direction of the cover is diffusely scattered at the microstructured surface.

In one embodiment of the optoelectronic component, the second section comprises a first partial region and a second partial region. In this case, the first partial region and the second partial region comprise different optical properties. This advantageously makes it possible to optimize the optical functionality of the cover further for a desired application.

In one embodiment of the optoelectronic component, the first partial region is arranged between the first section and the second partial region. In this case, the first partial region exhibits greater absorption than the second partial region. Advantageously, the first partial region of the second section of the cover may thereby serve as a light trap for light emitted by the emission surface in the direction of the cover.

In one embodiment of the optoelectronic component, the second partial region at least partly covers the first partial region. In this case, the second partial region comprises a higher reflectivity than the first partial region. Advantageously, the second partial region of the second section may thereby cause a particularly effective reflection of light incident on the second section of the cover from outside the optoelectronic component.

In one embodiment of the optoelectronic component, the emission surface is configured as an LED matrix. Advantageously, the optoelectronic component may thereby serve as an adaptive light source, for example as an adaptive headlight or as adaptive lighting for sensor system applications.

A method for manufacturing an optoelectronic component comprises steps for arranging an optoelectronic semiconductor chip comprising an emission surface arranged on a top side such that light may be emitted by the emission surface into an emission space, for creating a first section of a cover, which first section ring-shapedly bounds the emission surface, and for creating a second section of the cover. In this case, the first section and the second section are created in separate processes. The cover is configured such that light incident on the second section of the cover from outside the optoelectronic component is predominantly reflected. At the same time, the cover is configured such that light emitted by the emission surface in the direction of the cover is predominantly deflected by the cover such that it is not specularly reflected into the emission space.

Advantageously, an optoelectronic component whose cover fulfils two functionalities is obtainable by this manufacturing method. Light, for example sunlight, incident on the second section of the cover from outside the optoelectronic component is predominantly reflected, which reduces the risk of a material degradation in the optoelectronic component. Light emitted by the emission surface in the direction of the cover is predominantly deflected by the cover such that it is not specularly reflected into the emission space. Unwanted light reflections in the emission space are advantageously suppressed as a result.

In one embodiment of the method, the first section is configured as a dam. The second section is then configured as a potting extending as far as the dam. This advantageously enables simple and cost-effective manufacture of the cover of the optoelectronic component.

In one embodiment of the method, the first section is configured by way of a dosing method. This advantageously enables simple and cost-effective configuration of the first section of the cover.

The above-described properties, features and advantages of this invention and the way in which they are achieved will become clearer and more clearly understood in association with the following description of the exemplary embodiments which are explained in greater detail in association with the drawings, in which, in a schematic illustration:

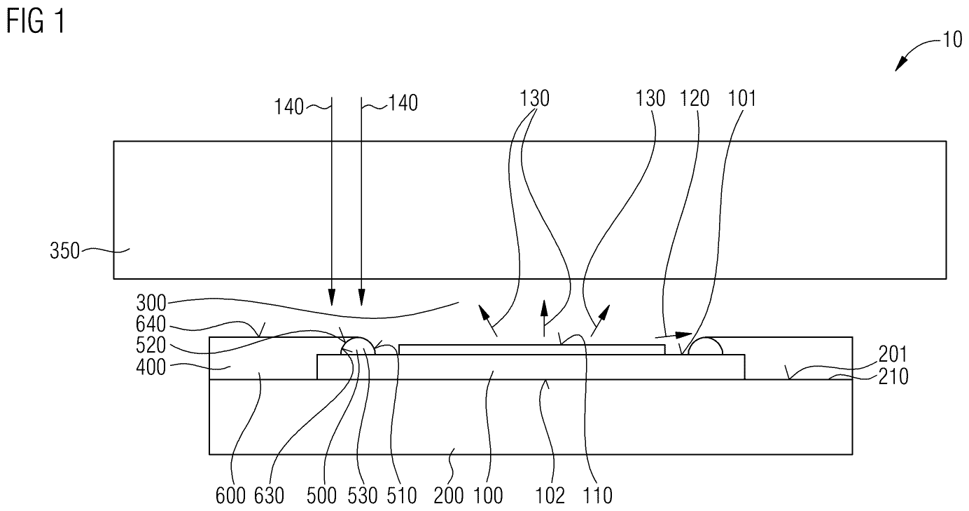

FIG. 1 shows a sectional side view of an optoelectronic component;

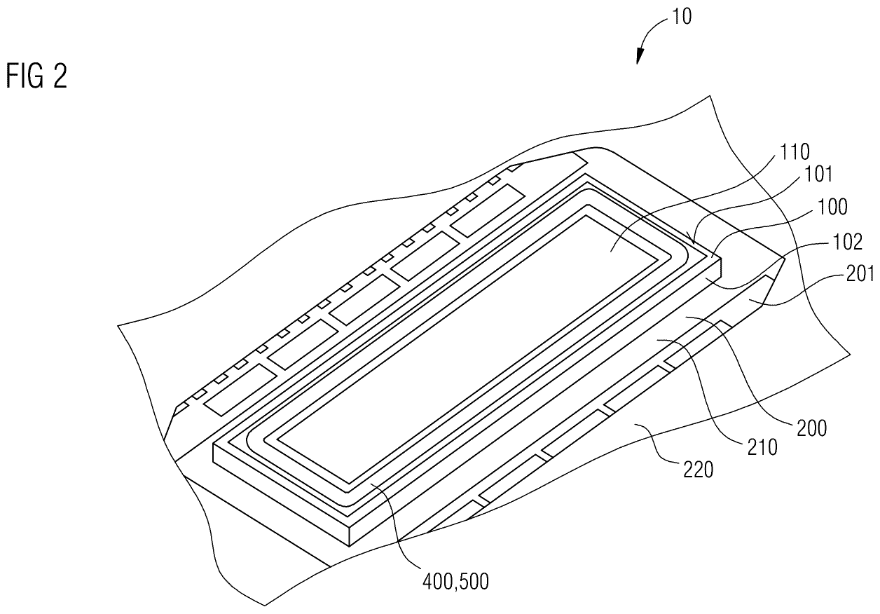

FIG. 2 shows a plan view of a part of the optoelectronic component in an unfinished processing state;

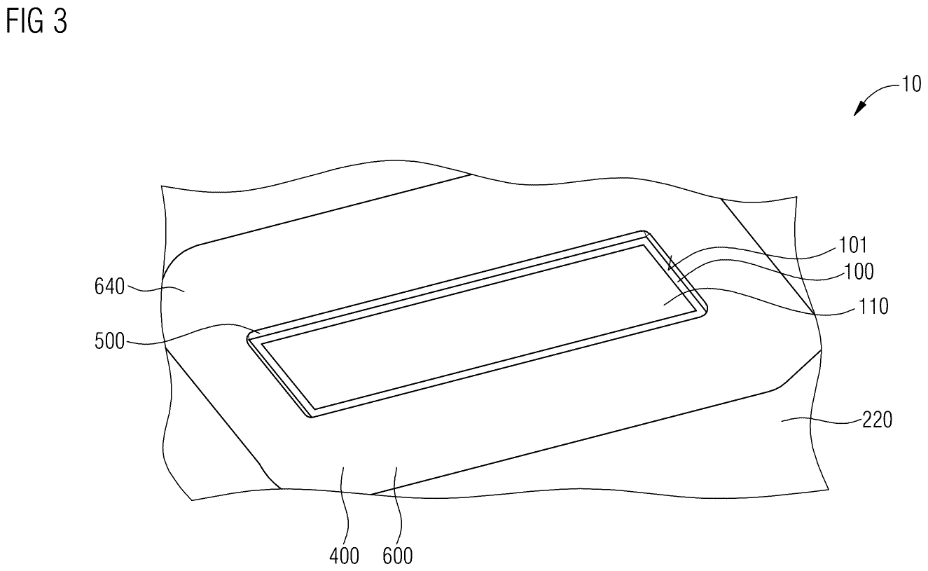

FIG. 3 shows a plan view of a part of the optoelectronic component in a subsequent processing state;

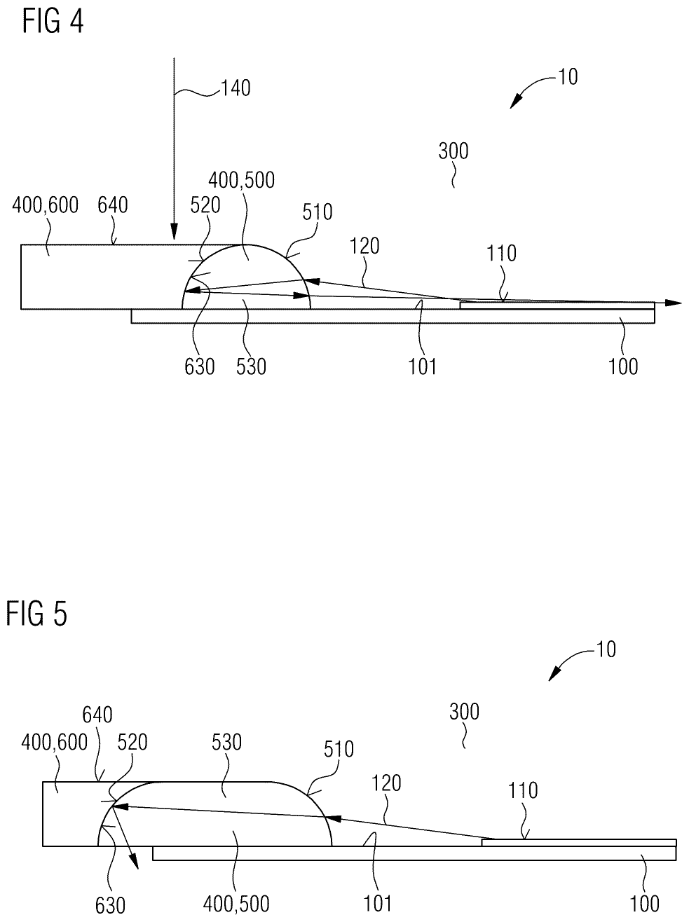

FIG. 4 shows a sectional side view of a first variant of a cover of the optoelectronic component;

FIG. 5 shows a further variant of the cover;

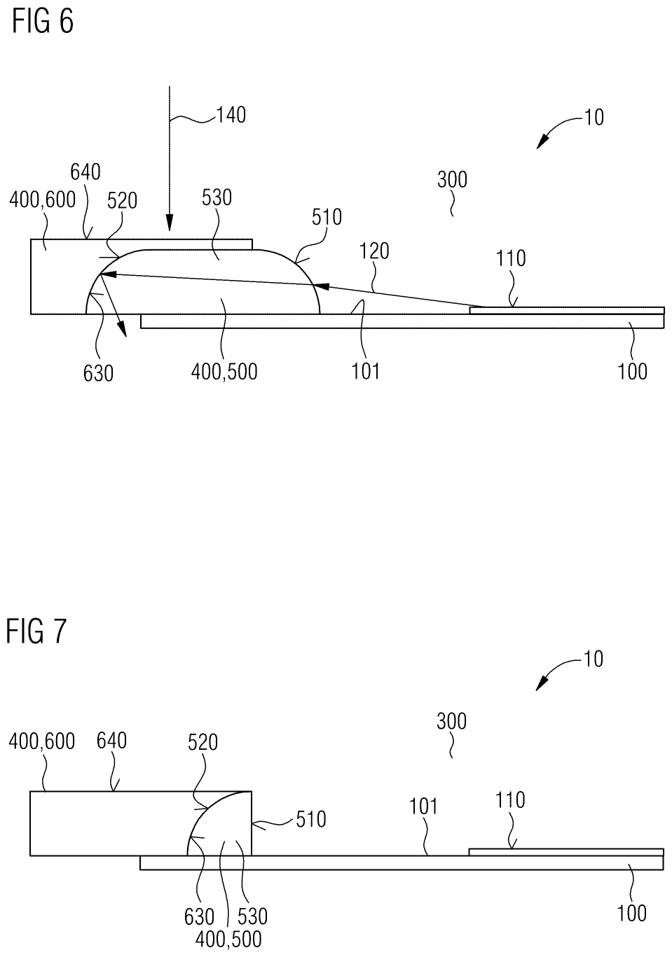

FIG. 6 shows a further variant of the cover;

FIG. 7 shows a further variant of the cover;

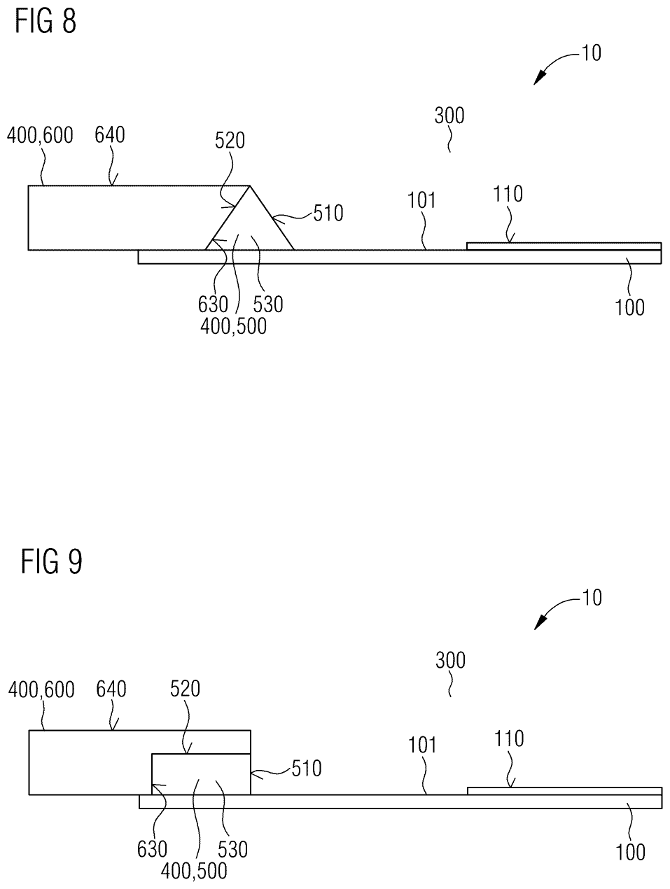

FIG. 8 shows a further variant of the cover;

FIG. 9 shows a further variant of the cover;

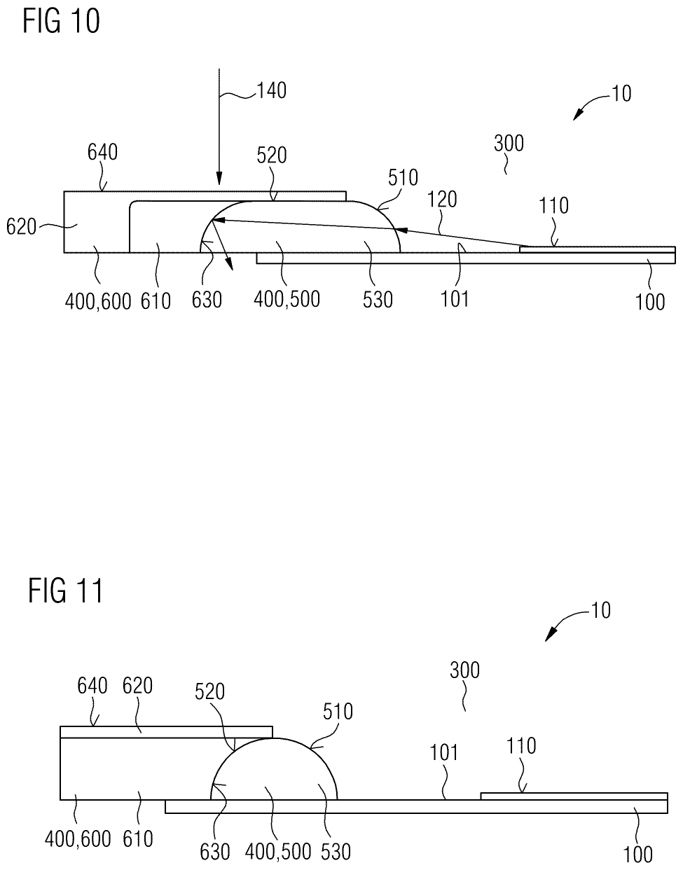

FIG. 10 shows a further variant of the cover;

FIG. 11 shows a further variant of the cover;

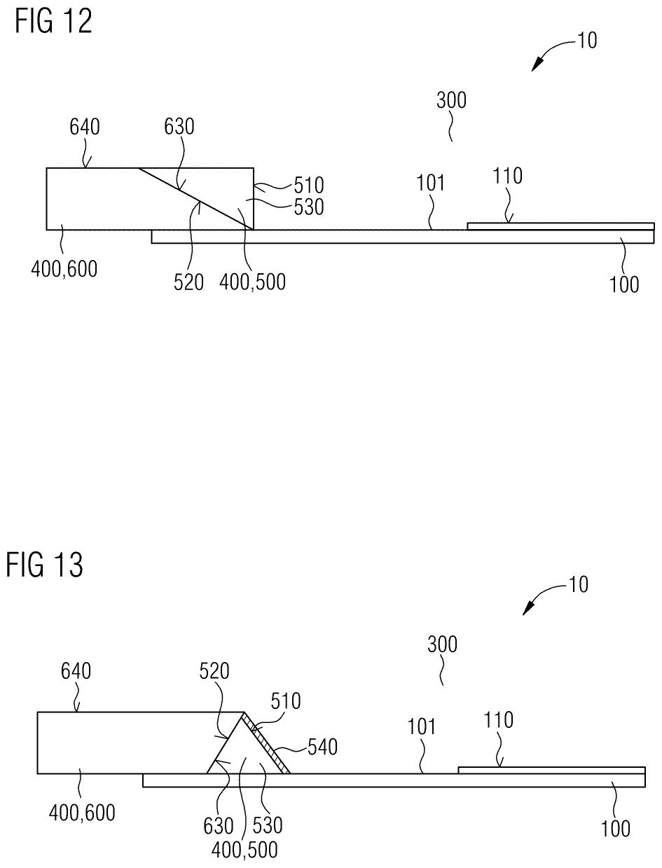

FIG. 12 shows a further variant of the cover; and

FIG. 13 shows a further variant of the cover of the optoelectronic component.

FIG. 1 shows a schematic sectional side view of a part of an optoelectronic component 10. The optoelectronic component 10 is provided for emitting light into a target space. The optoelectronic component 10 may for example be part of a headlight of an automobile or serve as a lighting device for a sensor system application.

The optoelectronic component 10 comprises a carrier 200 comprising a top side 201. The carrier 200 may be configured for example as a printed circuit board comprising a metallization 210 arranged on the top side 201.

An optoelectronic semiconductor chip 100 is arranged on the top side 201 of the carrier 200. The optoelectronic semiconductor chip 100 comprises a top side 101 and an underside 102 opposite the top side 101. The underside 102 faces the top side 201 of the carrier 200.

An emission surface 110 is arranged on the top side 101 of the optoelectronic semiconductor chip 100. The emission surface 110 is provided to emit light 103 into an emission space 300 above the top side 101 of the emission surface 110.

The emission surface 110 may be configured for example on a light-emitting semiconductor layer sequence, for example an LED layer sequence, which is arranged on the top side 101 of the optoelectronic semiconductor chip 100. In this case, the emission surface 110 may be subdivided for example into individually controllable light-emitting regions (pixels) arranged in the form of a matrix. In this case, the optoelectronic semiconductor chip 100 may for example be configured as a silicon chip and serve for controlling the light-emitting layer sequence.

However, by way of example, the optoelectronic semiconductor chip 100 itself may also be configured as a light-emitting semiconductor chip, for example as an LED chip.

The emission surface 110 may also be formed by a wavelength-converting layer. In this case, the wavelength-converting layer may be arranged on a light-emitting semiconductor layer sequence, which is in turn arranged on the top side 101 of the optoelectronic semiconductor chip 100. Alternatively, the wavelength-converting layer may be arranged on the optoelectronic semiconductor chip 100 itself configured as a light-emitting semiconductor chip. The wavelength-converting layer may be provided to convert light generated by the light-emitting semiconductor layer sequence or the optoelectronic semiconductor chip at least partly into light of a different wavelength. By way of example, the wavelength-converting layer may be provided to generate white mixed light.

In the example shown in FIG. 1, the optoelectronic component 10 additionally comprises a projection optics unit 350, which is arranged over the emission surface 110 in the emission space 300 such that light 130 emitted into the emission space 300 by the emission surface 110 passes into the projection optics unit 350. The projection optics unit 350 is provided to project the light emitted into the emission space 300 by the emission surface 110 into a target space. If the optoelectronic component 10 is part of a headlight of a motor vehicle, the projection optics unit 350 may serve for example to direct the light 130 emitted by the emission surface 110 onto a road. In one simplified variant of the optoelectronic component 10, the projection optics unit 350 may be omitted.

The optoelectronic component 10 furthermore comprises a cover 400, which laterally bounds the emission surface 110. The cover 400 comprises a first section 500, which ring-shapedly bounds the emission surface 110, and a second section 600. In the example shown in FIG. 1, the second section 600 is radially outwardly adjacent to the first section 500.

The cover 400 is provided to predominantly reflect light 140 incident on the second section 600 of the cover 400 from outside the optoelectronic component 10. The light 140 incident from outside the optoelectronic component 10 may be sunlight, for example, which passes into the inner region of the optoelectronic component 10 through the projection optics unit 350. In this case, under certain circumstances, the projection optics unit 350 may cause the light 140 incident from outside to be focused onto a small area. The largest possible portion of this light 140 needs to be reflected from the second section 600 of the cover 400 in order to prevent excessive heating and possibly attendant damage or degradation of component parts of the optoelectronic component 10. The light 140 reflected at the second section 600 of the cover 400 may then emerge again from the optoelectronic component 10 or pass into less sensitive regions of the optoelectronic component 10.

The cover 400 additionally has the task of predominantly deflecting light 120 emitted by the emission surface 110 in the direction of the cover 400 such that it is not specularly reflected into the emission space 300. The radiation emitted by the emission surface 110 is predominantly emitted into an angular range around a direction oriented perpendicularly to the emission surface 110 and may thus pass directly into the projection optics unit 350 as light 130 emitted into the emission space 300. However, a portion of the radiation emitted by the emission surface 110 may also be emitted in a lateral direction in such a way that it is incident on the cover 400 laterally bounding the emission surface 110. If this light 120 emitted in the direction of the cover 400 were reflected at the cover 400 in such a way that it subsequently passes into the emission space 300 and the projection optics unit 350, then it would be undesirably projected into the target space by the projection optics unit 350. This problem would be particularly serious if the light 120 emitted in the direction of the cover 400 were specularly reflected at the cover 400, since bright scattered light reflections might thereby be produced in the target space.

The cover 400 of the optoelectronic component 10 may be manufactured by the first section 500—which ring-shapedly bounds the emission surface 110—and the second section 600 of the cover 400 being created successively in separate processes. FIG. 2 shows a perspective plan view of a part of the optoelectronic component 10 in an unfinished processing state during the manufacture of the optoelectronic component 10. The projection optics unit 350 is not shown in the illustration in FIG. 2. Instead, FIG. 2 schematically also shows a part of a housing 220 of the optoelectronic component 10, said housing not being illustrated in FIG. 1. The housing 220 accommodates the carrier 200 and also covers a part of the top side 201 of the carrier 200. The optoelectronic semiconductor chip 100 is exposed in a recess of the housing 220.

In a processing step temporally preceding the processing state shown in FIG. 2, the first section 500 of the cover 400 was created, said first section ring-shapedly bounding the emission surface 110. In this case, the first section 500 was arranged on the top side 101 of the optoelectronic semiconductor chip 100. However, it would also be possible to arrange the first section 500 of the cover 400 partially or completely next to the optoelectronic semiconductor chip 100. The first section 500 may have been formed by way of a dosing method (dispensing), for example.

FIG. 3 shows a schematic perspective plan view of a part of the optoelectronic component 10 in a processing state temporally succeeding the illustration in FIG. 2. The second section 600 of the cover 400 was created such that it is radially outwardly adjacent to the first section 500. In the example shown in FIG. 3, the second section 600 extends as far as the edge of the recess of the housing 220 and thus covers the entire part of the top side 201 of the carrier 200 which previously was still exposed. The parts of the top side 101 of the optoelectronic semiconductor chip 100 radially outside the first section 500 of the cover 400 are also covered by the second section 600 of the cover 400. The cover 400 ring-shapedly encloses the still exposed emission surface 110 of the optoelectronic semiconductor chip 100.

The second section 600 of the cover 400 may have been formed by a potting method (casting) for example. In this case, the previously created first section 500 of the cover 400 may have served as a dam.

FIG. 4 shows a schematic sectional side view of a part of the optoelectronic component 10. The illustration shows a part of the optoelectronic semiconductor chip 100 comprising the emission surface 110 arranged on the top side 101, and a part of the cover 400 comprising the first section 500 and the second section 600.

The first section 500 of the cover 400 is arranged completely on the top side 101 of the optoelectronic semiconductor chip 100 and bounds the emission surface 110. The second section 600 is radially outwardly adjacent to the first section 500. The second section 600 is arranged sectionally on the top side 101 of the optoelectronic semiconductor chip 100, but extends laterally beyond the optoelectronic semiconductor chip 100 and is arranged there on the top side 201 of the carrier 200, not illustrated in FIG. 4.

In the example shown in FIG. 4, the first section 500 comprises a cross-section 530 comprising the approximate shape of half a circular disk. The surface of the first section 500 facing away from the top side 101 of the optoelectronic semiconductor chip 100 is thus approximately semicircularly curved in the cross-section 530. Said surface is subdivided into a surface 510 not covered by the second section 600 and a surface 520 covered by the second section 600.

In the example shown in FIG. 4, the second section 600 of the cover 400 extends in a direction perpendicular to the top side 101 of the optoelectronic semiconductor chip 100 as far as the vertex of the first section 500. The first section 500 and the second section 600 of the cover 400 thus comprise approximately the same thickness in a direction perpendicular to the top side 101 of the optoelectronic semiconductor chip 100. The consequence of this is that the uncovered surface 510 and the covered surface 520 of the first section 500 in the cross-section 530 are of approximately the same size. The uncovered surface 510 of the first section 500 is oriented in the direction of the emission surface 110 of the optoelectronic semiconductor chip 100.

The second section 600 of the cover 400 comprises a contact area 630 adjoining the covered surface 520 of the first section 500. Since the covered surface 520 of the first section 500 is convexly curved, the contact area 630 of the second section 600 comprises a concave shape. The contact area 630 thus forms a concave mirror. The contact area 630 is oriented toward the top side 101 of the optoelectronic semiconductor chip 100. This means that a normal vector at every part of the contact area 630 of the second section 600 is oriented toward the top side 101 of the optoelectronic semiconductor chip 100 or parallel to the top side 101 of the optoelectronic semiconductor chip 100.

The first section 500 and the second section 600 of the cover 400 comprise mutually different optical properties. This may be achieved for example by virtue of the first section 500 and the second section 600 comprising different materials. It is also possible for the first section 500 and the second section 600 to comprise identical matrix materials comprising different proportions of fillers.

In one example, the first section 500 comprises a higher transparency than the second section 600. The second section 600 comprises a higher reflectivity than the first section 500. For this purpose, the second section 600 may comprise for example a higher proportion of light-scattering particles than the first section 500. In the case where highly reflective white filling particles are used, the first section 500 may comprise for example a concentration of said filling particles of between 0 percent by weight and 10 percent by weight. In the case where less reflective filling particles are used, the first section 500 may comprise a concentration of said filling particles of between 0 percent by weight and 30 percent by weight. The second section 600 of the cover 400 may then comprise in each case a higher concentration of the filling particles. It is expedient if the first section 500 of the cover 400 comprises a material which comprises a transmission of at least 30% given a reference thickness of 100 μm.

Light 120 emitted by the emission surface 110 of the optoelectronic semiconductor chip 100 in the direction of the cover 400 at least partly enters the first section 500 of the cover 400 and is at least partly reflected at the contact area 630 of the second section 600 of the cover 400. By virtue of the concave-mirror-like concave shape of the contact area 630 oriented toward the top side 101 of the optoelectronic semiconductor chip 100, the light reflected at the contact area 630 is incident on the emission surface 110 again or passes over the emission surface 110 at a shallow angle. This prevents light 120 emitted by the emission surface 110 in the direction of the cover 400 from being specularly reflected into the emission space 300.

Light 140 incident on the second section 600 of the cover 400 from outside the optoelectronic component 10 is predominantly reflected at an outer surface 640 of the second section 600, which comprises a high reflectivity. The outer surface 640 is oriented approximately parallel to the top side 101 of the optoelectronic semiconductor chip 100, such that the light reflected at the outer surface 640 substantially leaves the optoelectronic component 10 again or passes into insensitive regions of the optoelectronic component 10.

In an alternative example, the first section 500 of the cover 400 is configured to be predominantly absorbent. In this example, too, the second section 600 comprises a high reflectivity, in particular a higher reflectivity than the first section 500. In this exemplary configuration, light 120 emitted by the emission surface 110 of the optoelectronic semiconductor chip 100 in the direction of the cover 400 is at least partly absorbed in the first section 500 of the cover 400. The rest of the light at least partly enters the first section 500 of the cover 400 and is at least partly reflected at the contact area 630 of the second section 600 of the cover 400 in the manner already described. This also prevents light 120 emitted by the emission surface 110 in the direction of the cover 400 from being specularly reflected into the emission space 300.

FIG. 5 shows a schematic sectional side view of a part of an alternative variant of the optoelectronic component 10. In the case of the variant shown in FIG. 5, the first section 500 of the cover 400 is widened in a radial direction by comparison with the variant shown in FIG. 4, such that the first section 500 projects laterally beyond the top side 101 of the optoelectronic semiconductor chip 100. The first section 500 of the cover 400 is thus arranged sectionally on the top side 101 of the optoelectronic semiconductor chip 100 and sectionally on the top side 201 of the carrier 200, not shown in FIG. 5. It would also be possible to arrange the first section 500 completely outside the optoelectronic semiconductor chip 100 on the top side 201 of the carrier 200. In the case of the variant shown in FIG. 5, light 120 that is emitted by the emission surface 110 in the direction of the cover 400 and is reflected at the contact area 630 of the second section 600 of the cover 400 may emerge from the first section 500 of the cover 400 at least partly in an opposite direction to the emission space 300, as a result of which it is guided at least partly past the optoelectronic semiconductor chip 100. The light guided past the optoelectronic semiconductor chip 100 in the opposite direction to the emission space 300 may for example pass into a light trap or be reflected or absorbed at the top side 201 of the carrier 200. In any case this prevents light 120 emitted by the emission surface 110 in the direction of the cover 400 from being specularly reflected into the emission space 300.

FIG. 6 shows a schematic sectional side view of a part of an alternative variant of the optoelectronic component 10. In the case of the variant shown in FIG. 6, the second section 600 extends over a larger part of the surface of the first section 500 than in the case of the variant shown in FIG. 5. The second section 600 thus comprises a somewhat larger thickness than the first section 500 in a direction measured perpendicularly to the top side 101 of the optoelectronic semiconductor chip 100. In the case of the variant shown in FIG. 6, the uncovered surface 510 of the first section 500 is smaller than the covered surface 520 and smaller than in the case of the variant shown in FIG. 5. What is achieved as a result is that light 140 incident, from outside the optoelectronic component 10, on that part of the second section 600 of the cover 400 which is arranged over the surface of the first section 500 is predominantly reflected.

The second section 600 of the cover 400 of the variant of the optoelectronic component 10 shown in FIG. 6 might also be configured in a bipartite fashion, as will also be described below with reference to FIG. 11.

FIG. 7 shows a schematic sectional side view of a part of a further variant of the optoelectronic component 10. The variant shown in FIG. 7 differs from the variant shown in FIG. 4 in that the cross-section 530 of the first section 500 of the cover 400 does not comprise the shape of half a circular disk. Instead, in the case of the variant shown in FIG. 7, the cross-section 530 approximately comprises the shape of a quarter of a circular disk. As a result, the surface 510 which faces the emission surface 110 of the optoelectronic semiconductor chip 100 and is not covered by the second section 600 is planar and oriented approximately perpendicularly to the top side 101 of the optoelectronic semiconductor chip 100. In the case of the variant shown in FIG. 7, the shape of the surface 520 of the first section 500 which is covered by the second section 600 and the shape of the contact area 630 of the second section 600 correspond to the variant in FIG. 4.

FIG. 8 shows a schematic sectional side view of a part of a further variant of the optoelectronic component 10. The variant shown in FIG. 8 differs from the variant illustrated in FIG. 4 in that the cross-section 530 of the first section 500 of the cover 400 comprises an approximate triangular shape. As a result, pertaining to the first section 500, both the surface 510 not covered by the second section 600 and the surface 520 covered by the second section 600 are configured in planar fashion and are each inclined relative to an orientation perpendicular to the top side 101 of the optoelectronic semiconductor chip 100. Accordingly, the contact area 630 of the second section 600 of the cover 400 is also configured in planar fashion. Nevertheless, the contact area 630 of the second section 600 is oriented toward the top side 101 of the optoelectronic semiconductor chip 100 in the case of the variant shown in FIG. 8, too.

FIG. 9 shows a schematic sectional side view of a part of a further variant of the optoelectronic component 10. In the case of the variant shown in FIG. 9, the cross-section 530 of the first section 500 of the cover 400 comprises an approximate rectangular shape. Moreover, in the case of this variant, in a manner similar to that in the case of the variant in FIG. 6, the second section 600 of the cover 400 extends partly over the first section 500, such that the second section 600 comprises a greater thickness than the first section 500 in a direction perpendicular to the top side 101 of the optoelectronic semiconductor chip 100.

FIG. 10 shows a schematic sectional side view of a part of a further variant of the optoelectronic component 10. In the case of the variant shown in FIG. 10, the cover 400 comprises a shape similar to that in the case of the variant shown in FIG. 6. However, the second section 600 of the cover 400 is subdivided into a first partial region 610 and a second partial region 620. The first partial region 610 is arranged between the first section 500 of the cover 400 and the second partial region 620. The first partial region 610 of the second section 600 thus forms the contact area 630 in contact with the first section 500. The second partial region 620 of the second section 600 forms the outer surface 640 of the second section 600 of the cover 400.

The first partial region 610 and the second partial region 620 of the second section 600 comprise different optical properties. The first partial region 610 exhibits greater absorption than the second partial region 620. The optical properties of the second partial region 620 of the second section 600 may correspond to the optical properties of the second section 600 of the cover 400 that were described with reference to FIG. 4.

In the case of the variant of the optoelectronic component 10 shown in FIG. 10, light 120 emitted by the emission surface 110 in the direction of the cover 400 is at least partly reflected at the contact area 630. However, a portion of the light 120 emitted by the emission surface 110 in the direction of the cover 400 may also penetrate into the first partial region 610 of the second section 600 and be absorbed there. The first partial region 610 of the second section 600 of the cover 400 thus forms a light trap.

By contrast, in the case of the variant shown in FIG. 10, too, light 140 incident on the second section 600 of the cover 400 from outside the optoelectronic component 10 is predominantly reflected at the outer surface 640 of the second section 600, said outer surface being formed by the second partial region 620 of the second section 600, and does not pass to the first partial region 610 of the second section 600.

The first partial region 610 and the second partial region 620 of the second section 600 of the cover 400 of the variant of the optoelectronic component 10 shown in FIG. 10 may be manufactured successively in two separate processing steps. In this case, firstly, the first partial region 610 is manufactured. Afterward, the second partial region 620 is created.

FIG. 11 shows a schematic sectional side view of a part of a further variant of the optoelectronic component 10. The variant shown in FIG. 11 differs from the variant of the optoelectronic component 10 described with reference to FIG. 4 in that the second section 600 of the cover 400 is subdivided into a first partial region 610 and a second partial region 620. The second partial region 620 at least partly covers the first partial region 610. In the example shown in FIG. 11, the second partial region 620 completely covers the first partial region 610, such that the outer surface 640 of the second section 600 is formed by the second partial region 620. The first partial region 610 of the second section 600 is in contact with the covered surface 520 of the first section 500, such that the contact area 630 of the second section 600 is formed by the first partial region 610 of the second section 600.

The first partial region 610 and the second partial region 620 of the second section 600 comprise different optical properties. The second partial region 620 comprises a higher reflectivity than the first partial region 610. The second partial region 620 of the second section 600 of the cover 400 of the variant of the optoelectronic component 10 shown in FIG. 11 may comprise for example the same material and the same optical properties as the second section 600 of the variant of the optoelectronic component 10 described with reference to FIG. 4. The first partial region 610 of the second section 600 of the cover 400 of the variant shown in FIG. 11 may comprise a lower reflectivity.

The first partial region 610 and the second partial region 620 of the second section 600 of the cover 400 of the variant of the optoelectronic component 10 shown in FIG. 11 may be manufactured successively in two separate processing steps.

In this case, firstly, the first partial region 610 is created. Afterward, the second partial region 620 is created.

FIG. 12 shows a schematic sectional side view of a part of a further variant of the optoelectronic component 10. The variant of the optoelectronic component 10 shown in FIG. 12 differs from the variant shown in FIG. 4 in that the first section 500 of the cover 400 comprises a cross-section 530 comprising an approximately triangular shape. The contact area 630 of the second section 600 is configured in substantially planar fashion and is not oriented toward the top side 101 of the optoelectronic semiconductor chip 100, but rather oriented toward the emission space 300.

In the case of the variant of the optoelectronic component 10 shown in FIG. 12, light 120 emitted by the emission surface 110 in the direction of the cover 400 may penetrate into the first section 500 of the cover 400 and is at least partly reflected at the contact area 630 of the second section 600. In this case, the contact area 630 is oriented such that the light reflected at the contact area 630 does not pass into the emission space 300 and, as a result, does not pass into the projection optics unit 350 either.

FIG. 13 shows a schematic sectional side view of a part of a further variant of the optoelectronic component 10. The variant shown in FIG. 13 corresponds to the variant described with reference to FIG. 8. In the case of the variant in FIG. 13, a microstructuring 540 is additionally provided on the surface 510 of the first section 500 which is not covered by the second section 600. The microstructuring 540 may be for example a roughening, in particular a statistical roughening. The microstructuring 540 may have the effect that light 120 emitted by the emission surface 110 in the direction of the cover 400 is at least partly diffusely scattered by the microstructuring 540. As a result, the microstructuring 540 prevents light 120 emitted by the emission surface 110 in the direction of the cover 400 from being specularly reflected into the emission space 300. In the case, too, of the further variants of the optoelectronic component 10 described with reference to FIGS. 4 to 12, a corresponding microstructuring 540 may be provided on the surface 510 of the first section 500 of the cover 400 which is not covered by the second section 600.

### List of Reference Signs

10 Optoelectronic component
100 Optoelectronic semiconductor chip
101 Top side
102 Underside
110 Emission surface
120 Light emitted in the direction of the cover
130 Light emitted into emission space
140 Light incident from outside
200 Carrier
201 Top side
210 Metallization
220 Housing
300 Emission space
350 Projection optics unit
400 Cover
500 First section
510 Uncovered surface
520 Covered surface
530 Cross-section
540 Microstructuring
600 Second section
610 First partial region
620 Second partial region
630 Contact area
640 Outer surface

1. An optoelectronic component
comprising an optoelectronic semiconductor chip comprising an emission surface arranged on a top side, the emission surface being provided to emit light into an emission space,
wherein the emission surface is laterally bounded by a cover,
wherein the cover comprises a first section, which ring-shapedly bounds the emission surface, and a second section,
wherein the cover is configured such that light incident on the second section of the cover from outside the optoelectronic component is predominantly reflected,
and light emitted by the emission surface in the direction of the cover is predominantly deflected by the cover such that it is not specularly reflected into the emission space.

2. The optoelectronic component as claimed in claim 1,
wherein the optoelectronic component comprises a projection optics unit arranged over the emission surface such that light emitted into the emission space passes into the projection optics unit.

3. The optoelectronic component as claimed in claim 1,
wherein the emission surface covers a part of the top side of the optoelectronic semiconductor chip,
wherein the first section of the cover is arranged at least sectionally on the top side of the optoelectronic semiconductor chip.

4. The optoelectronic component as claimed in claim 1,
wherein light emitted by the emission surface in the direction of the cover is guided past the optoelectronic semiconductor chip at least partly in an opposite direction to the emission space.

5. The optoelectronic component as claimed in claim 1,
wherein the second section is radially outwardly adjacent to the first section.

6. The optoelectronic component as claimed in claim 5,
wherein the second section comprises a contact area adjoining the first section,
wherein light emitted by the emission surface in the direction of the cover is at least partly reflected at the contact area.

7. The optoelectronic component as claimed in claim 6,
wherein the contact area comprises a concave shape.

8. The optoelectronic component as claimed in claim 6,
wherein the contact area is oriented toward the top side of the optoelectronic semiconductor chip.

9. The optoelectronic component as claimed in claim 1,
wherein the first section and the second section comprise different optical properties, in particular a different transparency and/or a different reflectivity.

10. The optoelectronic component as claimed in claim 9,
wherein the first section and the second section comprise different materials.

11. The optoelectronic component as claimed in claim 9,
wherein the second section comprises a higher proportion of light-scattering particles than the first section.

12. The optoelectronic component as claimed in claim 1,
wherein the first section comprises a material which comprises a transmission of at least 30% given a reference thickness of 100 μm.

13. The optoelectronic component as claimed in claim 1,
wherein a surface of the first section that is not covered by the second section comprises a microstructuring.

14. The optoelectronic component as claimed in claim 1,
wherein the second section comprises a first partial region and a second partial region,
wherein the first partial region and the second partial region comprise different optical properties.

15. The optoelectronic component as claimed in claim 14,
wherein the first partial region is arranged between the first section and the second partial region,
wherein the first partial region exhibits greater absorption than the second partial region.

16. The optoelectronic component as claimed in claim 14,
wherein the second partial region at least partly covers the first partial region,
wherein the second partial region comprises a higher reflectivity than the first partial region.

17. The optoelectronic component as claimed in claim 1,
wherein the emission surface is configured as an LED matrix.

18. A method for manufacturing an optoelectronic component comprising the following steps:
arranging an optoelectronic semiconductor chip comprising an emission surface arranged on a top side such that light may be emitted by the emission surface into an emission space,
creating a first section of a cover, which first section ring-shapedly bounds the emission surface,
creating a second section of the cover,
wherein the first section and the second section are created in separate processes,
wherein the cover is configured such that light incident on the second section of the cover from outside the optoelectronic component is predominantly reflected,
and light emitted by the emission surface in the direction of the cover is predominantly deflected by the cover such that it is not specularly reflected into the emission space.

19. The method as claimed in claim 18,
wherein the first section is configured as a dam,
and the second section is configured as a potting extending as far as the dam.

20. (canceled)

21. An optoelectronic component
comprising an optoelectronic semiconductor chip comprising an emission surface arranged on a top side, the emission surface being provided to emit light into an emission space,
wherein the emission surface is laterally bounded by a cover,
wherein the cover comprises a first section, which ring-shapedly bounds the emission surface, and a second section,
wherein the second section is radially outwardly adjacent to the first section,
wherein the second section comprises a contact area adjoining the first section,
wherein the cover is configured such that light incident on the second section of the cover from outside the optoelectronic component is predominantly reflected,
and light emitted by the emission surface in the direction of the cover is predominantly deflected by the cover such that it is not specularly reflected into the emission space,
wherein light emitted by the emission surface in the direction of the cover is at least partly reflected at the contact area.
